(19) United States
(12) Patent Application Publication
(10) Pub. No.: US 2006/0109156 A1
(43) Pub. Date: May 25, 2006

(54) Trimming resistance ladders in analog-digital converters

(75) Inventors: Roger Colbeck, Stittsville (CA); Ognjen Brkic, Markham (CA)

Correspondence Address: SMART & BIGGAR;P.O. BOX 2999, STATION D, 900-55 METCALFE STREET, OTTAWA, ON, K1P5Y6, CA

(73) Assignee: Potentia Semiconductor Corporation

(21) Appl. No.: 11/282,741

(22) Filed: Nov. 21, 2005

Related U.S. Application Data
(60) Provisional application No. 60/628,947, filed on Nov. 19, 2004.

(51) Int. Cl. H03M 1/78

(52) U.S. Cl. 341/154

(57) ABSTRACT

A resistance ladder comprises a plurality of resistors in series, with taps for producing comparison voltage levels for an analog-to-digital converter (ADC), coupled at its ends to reference and common voltages via first and second adjustable resistances. The reference voltage is produced by an amplifier whose gain depends on a resistance ratio that is trimmed to determine a gain or full-scale range of the ADC. Offset trimming for the ADC is provided by making equal and opposite changes to the first and second adjustable resistances, so that the full-scale range is unchanged and the offset and gain adjustments are independent of one another.

This application claims the benefit of U.S. Provisional Application No. 60/628,947 filed Nov. 19, 2004, the entire contents and disclosure of which are hereby incorporated herein by reference.

This invention relates to analog-to-digital converters (ADCs), and to trimming a resistance ladder which can form part of an ADC.

### BACKGROUND

ADCs in integrated circuits are well known. For example, in the book “Introduction To CMOS Op-Amps And Comparators” by R. Gregorian, John Wiley & Sons, 1999, chapter 7 at pages 255-302, which is hereby incorporated herein by reference, describes various forms and characteristics of known ADCs. Various ones of these use a resistance ladder which is supplied with a reference voltage to provide a plurality of voltages for comparison purposes in the ADC process.

By way of example, one application of an ADC is for power management and supervision functions in switch mode power supplies (SMPSs) or dc/dc converters. In such an application it may be desired to measure an SMPS output voltage accurately and to convert it to a digital value, for example with an absolute accuracy of about 0.1%, requiring a 10-bit ADC.

For example, a coarse-fine successive approximation ADC, similar to those described in the above reference, can be provided using a resistance ladder for the first or coarse stage and a capacitance ladder for the second or fine stage.

Modern CMOS integrated circuits generally provide good enough resistance and capacitance matching that 10-bit performance can be achieved without trimming, at least in terms of DNL (differential nonlinearity level) and INL (integral nonlinearity level). However, it is difficult to obtain the required absolute performance because of non-idealities that create offset and gain errors. Although some applications of ADCs are tolerant of such errors, the application of an ADC referred to above is like a digital voltmeter, and requires the absolute accuracy.

Accordingly, obtaining the desired 0.1% absolute accuracy requires auto-calibration or factory-calibration to remove offset and gain errors. Factory trim or calibration is common in the industry, using switching in or out of resistors or capacitors in discrete steps.

It can be desirable to operate an ADC from a single, e.g. positive, supply rail to convert positive voltages within an ADC range that extends down to ground or 0V. However, offset trim in the region of 0V is difficult because it requires small negative voltages as well as small positive voltages. This difficulty can be avoided, at least in the application of the ADC referred to above, by not carrying out conversions all the way to ground (0V). The ADC instead can have a zero digital code output that corresponds to a small positive voltage, for example about 100 mV, constituting the low end of the ADC range. However, this also undesirably changes the full-scale range of the ADC. Thus gain and offset trimming are not independent of one another, and calibration of the ADC can become complicated and/or inconvenient.

The invention facilitates providing a method and ADC arrangements which can avoid or reduce this disadvantage.

### SUMMARY OF THE INVENTION

According to one aspect, this invention provides a circuit including a resistance ladder comprising a plurality of resistors connected in series between first and second adjustable resistances via which a voltage difference is supplied to the resistance ladder, so that taps of the resistance ladder provide respective voltage levels over a voltage range, and a control circuit for making substantially equal and opposite changes to the first and second adjustable resistances to shift the voltage range without changing a magnitude of the voltage range.

In particular, the circuit can comprise an analog-to-digital converter (ADC) and the respective voltage levels provided by taps of the resistance ladder can constitute comparison voltage levels for the ADC. Typically said plurality of resistors of the resistance ladder have equal resistances.

Each of the first and second adjustable resistances can comprise a first resistor and a plurality of second resistors for connection selectively in parallel with the first resistor. This is particularly advantageous when the circuit is an integrated circuit.

Another aspect of the invention provides an analog-to-digital converter (ADC) comprising: a circuit for producing a reference voltage relative to a common voltage; a resistance ladder comprising a plurality of resistors connected in series between first and second adjustable resistances, the reference voltage and the common voltage being applied to the resistance ladder via the first and second adjustable resistances respectively, taps of the resistance ladder providing respective comparison voltage levels over a voltage range of the ADC; and a control circuit for making substantially equal and opposite resistance changes to the first and second adjustable resistances to shift the voltage range of the ADC without changing a magnitude of the voltage range.

The circuit for producing a reference voltage relative to a common voltage can comprise an amplifier for multiplying a voltage supplied to the amplifier in accordance with a gain of the amplifier determined by a resistance ratio.

A further aspect of the invention provides a method of trimming a resistance ladder, the resistance ladder comprising a plurality of resistors connected in series and having taps providing respective voltage levels over a voltage range in response to a voltage difference supplied to the resistance ladder, the method comprising the steps of: supplying a voltage difference to the resistance ladder via first and second adjustable resistances at first and second ends of the plurality of resistors connected in series; and making substantially equal and opposite changes to the first and second adjustable resistances to shift the voltage range without changing its magnitude.

Conveniently the step of making substantially equal and opposite changes to the first and second adjustable resistances is a step in fabricating an integrated circuit including the resistance ladder.

The method can also comprise the steps of producing the voltage difference using an amplifier having a gain determined by a resistance ratio, and adjusting a resistance of at least one resistor to control the resistance ratio thereby to determine the gain of the amplifier. The resistance ladder and amplifier can be parts of an analog-to-digital converter (ADC), and said steps of making substantially equal and opposite changes to the first and second adjustable resistances and adjusting the resistance of at least one resistor can comprise independent steps of adjusting offset and gain respectively of the ADC.

### BRIEF DESCRIPTION OF THE DRAWINGS

The invention will be further understood from the following description by way of example with reference to the accompanying drawings, in which:

FIG. 1 shows a block diagram of a successive approximation ADC using a resistance ladder, in accordance with an embodiment of the invention; and

FIG. 2 illustrates in greater detail one form of the resistance ladder and arrangements for trimming it.

### DETAILED DESCRIPTION

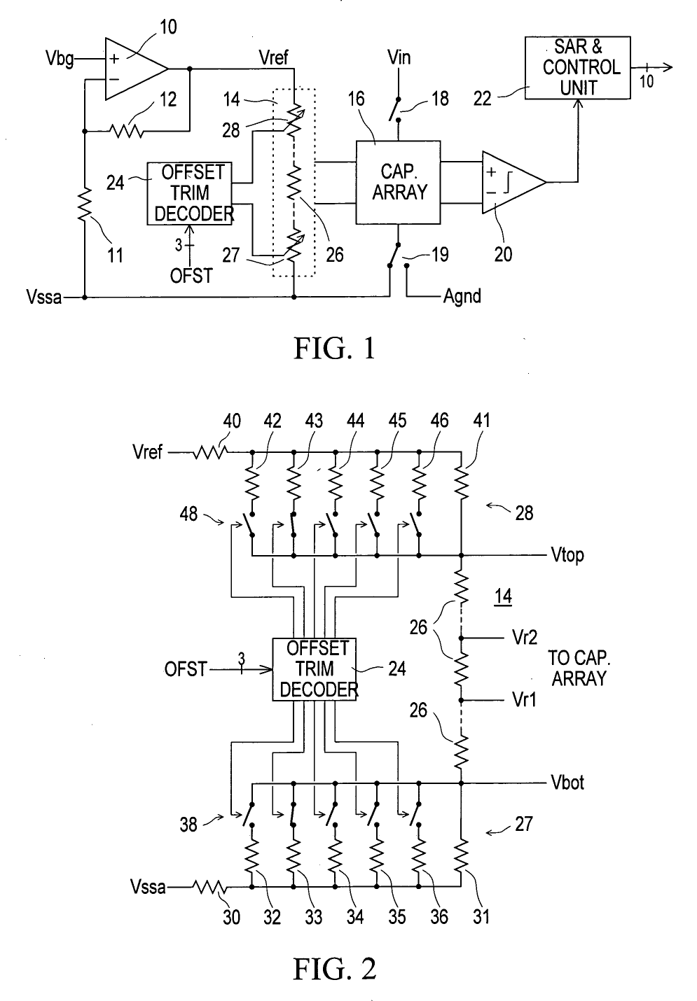

Referring to the drawings, FIG. 1 illustrates a block diagram of a 10-bit coarse-fine successive approximation ADC (analog-to-digital converter) using a resistance ladder or chain for the coarse stage and a capacitance ladder or array for the fine stage, and shows how an embodiment of the invention is applied to the ADC, the general form of which is known for example from the book by R. Gregorian referred to above.

More particularly, as shown in FIG. 1 the ADC comprises a source of a reference voltage Vref, constituted in this example by a differential amplifier 10 and resistors 11 and 12; a resistance ladder or chain 14, shown within a dashed line box; a capacitance ladder or array 16 and associated switches of which only two switches 18 and 19 are shown; a comparator 20; and a 10-bit SAR (successive approximation register) and control unit 22. The control unit 22 serves in a known manner to control the ADC and its switches to implement binary search and successive approximation algorithms, thereby producing a 10-bit digital output representing an input voltage Vin that is sampled by the switch 18. In addition, the ADC includes an offset trim decoder 24 as described further below.

By way of example, the resistance ladder 14 comprises a chain of 16 resistors of equal resistance, which divide a full-scale voltage range of the ADC into 16 consecutive sub-ranges or coarse voltage steps. In known manner the ADC, under the control of the control unit 22, performs a binary search algorithm to determine which of these sub-ranges or coarse steps includes a sampled value of the input voltage Vin; this determines the 4 most significant bits of the digital output, and selects the respective voltage sub-range to be supplied to the capacitance array 16.

In addition, in known manner the ADC, again under the control of the control unit 22, performs a successive approximation algorithm using the capacitance array 16, comparator 20, and SAR to determine the remaining 6 bits of the digital output. The ADC operation further includes offset compensation to compensate for offset of the comparator 20, and control of the switch 19 to select between a common (e.g. zero) voltage Vssa and an analog ground reference Agnd, in known manner.

FIG. 1 shows only one of the 16 resistors of equal resistance within the resistance ladder 14, referenced 26, and indicates the others by dashed lines. The resistance ladder 14 also includes a bottom resistance 27 via which a lower voltage end of the resistance chain is connected to the common voltage Vssa, and a top resistance 28 via which an upper voltage end of the resistance chain is connected to the voltage reference Vref. The bottom and top resistances 27 and 28 are adjustable or trimmable under the control of the offset trim decoder 24, which decodes a 3-bit offset trim control signal OFST supplied to it from the control unit 22, as further described below.

The reference voltage Vref and the relative resistances within the resistance ladder 14 thus determine the value of the input voltage Vin that corresponds to a zero digital output, the voltage difference of the input voltage Vin that corresponds to a change by one of the digital output, referred to as 1 LSB (least significant bit), and the full-scale voltage range of the ADC.

The amplifier 10 has its non-inverting input supplied with a precise and stable voltage Vbg, for example from a bandgap voltage source (not shown), and its inverting input connected via the resistor 11 to the voltage Vssa and via the resistor 12 to the output of the amplifier 10. If R1 and R2 are the resistances of the resistors 11 and 12 respectively, then the reference voltage Vref is given by the equation:
Vref=(1+R2/R1)Vbg
and (1+R2/R1) is the gain of the amplifier 10.

Thus the reference voltage Vref is controlled by trimming the ratio R2/R1. This trimming can be carried out at the wafer or package level in known manner using selectable resistors and CMOS switches, and compensates for offset in the amplifier 10 or other downstream effects in the ADC that might make the LSB size non-ideal.

The ADC of FIG. 1 is arranged to operate from a single voltage supply rail to convert input voltages in an approximate range of 0V to 2.5V. As observed above, offset trim in the region of 0V is difficult because it requires small positive and negative voltages. A need for negative voltages, and hence for a negative voltage supply as well as a positive voltage supply, is avoided in the ADC of FIG. 1 by shifting the zero code voltage of the ADC to a small positive value by providing the bottom resistance 27 connected to the common or zero voltage Vssa. The magnitude of the bottom resistance 27 is adjusted to reduce offset (a difference between the actual and nominal zero code voltages) as described further below.

Thus if a measurement of the ADC performance determines that the zero digital code corresponds to a voltage that is offset positively or negatively from its nominal and designed value, then the bottom resistance 27 is adjusted to reduce or increase, respectively, this voltage so that it is closer to the nominal value.

In known arrangements this would also change the total resistance of the resistance ladder 14, and hence the full-scale range and the LSB size of the ADC, thereby impairing its absolute accuracy. Correction of these would entail a further adjustment of the reference voltage Vref by further trimming of the resistor ratio R2/R1, with these two interdependent trimming processes being repeated successively until a desired accuracy is achieved. Thus in known arrangements, which do not have an adjustable top resistance, the trimming for gain and offset are not independent of one another.

The ADC of FIG. 1 avoids this by also providing the top resistance 28 and trimming its value in a substantially equal and opposite manner to any trimming of the bottom resistance 27. Consequently, a substantially constant total resistance is achieved for the whole of the resistance ladder 14, and offset trim adjustments of the resistances 27 and 28 do not change this and hence do not change the full-scale range or the LSB size of the ADC. In consequence, the gain and offset trim adjustments are independent of one another, and trimming or calibration of the ADC is considerably simplified. For the offset trimming, the offset trim decoder is supplied with the 3-bit control signal OFST, and decodes this to produce control signals for adjusting the resistances 27 and 28 as described in detail below.

The description below refers to specific voltages and resistances to assist in providing a full understanding, and it will be appreciated that these specific values, and other specific values given herein, are provided purely by way of example and that the invention is not limited by these in any respect.

For example, it is assumed that the resistances R2 and R1 are trimmed to provide a value of the reference voltage Vref of 2.835V. The 16 (in this example) resistors 26 can each have a resistance of 3 kΩ, and the top and bottom resistances 27 and 28 can each have a nominal resistance of about 2576.5Ω to provide the ADC with a coarse voltage step size of 0.16V, a LSB size of 2.5 mV, and a full-scale range of 2.56 V extending from a low end or zero code voltage of 0.1375V to a high end or full-scale voltage of 2.6975V.

With such an ADC it may be desired for example to provide offset trim adjustments within a range of ±½ LSB in ±¼ LSB steps. Thus the offset trim voltage is one of five values: −1.25 mV (−½ LSB), −0.625 mV (−¼ LSB), 0, +0.625 mV (+ 1/4 LSB), and +1.25 mV (+½ LSB). The whole of the full-scale range of the ADC is moved up or down by this offset trim voltage, relative to the nominal low end or zero code voltage of 0.1375V, upon adjustment of the bottom and top resistances 27 and 28 under the control of the decoder 24.

With the values given above by way of example, the offset voltage adjustment step size of 0.625 mV corresponds to a resistance change of 11.76Ω of each of the bottom and top resistances 27 and 28 in opposite directions. This is not practical to achieve with series resistors in CMOS technology, for which a unit square of low frequency polysilicon has a resistance of the order of 65Ω. However, such small resistance steps can be provided by a parallel resistor arrangement, for example as described below with reference to FIG. 2.

FIG. 2 shows in greater detail one form of the resistance ladder 14 and the offset trim decoder 24. In FIG. 2, the two end ones and one intermediate one of the 16 equal-valued resistors are illustrated, the others being indicated by dashed lines. Lower and upper voltages Vr1 and Vr2 respectively, defining whichever one of the 16 coarse voltage steps is selected during the binary search referred to above, appearing across one of the 16 resistors 26 and differing by the coarse voltage step size of 0.16V, are supplied to the capacitance array (not shown in FIG. 2). Lower and upper end voltages Vbot and Vtop respectively, constituting the full-scale voltage range of the ADC, are produced at the lower and upper ends of the chain of equal-valued resistors 26.

The bottom resistance 27, between the voltages Vssa and Vbot, is illustrated in FIG. 2 as comprising a fixed resistor 30 for example of resistance 2031Ω in series with a fixed resistor 31 for example of resistance 600Ω, and five resistors 32 to 36 a selected one of which is connected in parallel with the resistance 31 by a respective one of five switches 37 controlled by respective lower switch control outputs of the decoder 24. Similarly, the top resistance 28, between the voltages Vref and Vtop, is illustrated in FIG. 2 as comprising a fixed resistor 40 for example of resistance 2031Ω in series with a fixed resistor 41 for example of resistance 600Ω, and five resistors 42 to 46 a selected one of which is connected in parallel with the resistance 41 by a respective one of five switches 47 controlled by respective upper switch control outputs of the decoder 24.

For example, the resistors 32 to 36 can have resistances of 4 kΩ, 4.8 kΩ, 6 kΩ, 8 kΩ, and 11.1 kΩ respectively, so that in parallel with the 600 Ω resistor 31 they produce resistance values of about 521.7Ω, 533.3Ω, 545.5Ω, 558.1Ω, and 569.2Ω respectively. These resistance values are stepped with differences of about 11.76Ω, as required for voltage shift steps of about 0.625 mV or one quarter LSB as described above. Conversely, the resistors 42 to 46 can have resistances of 11.1 kΩ, 8 kΩ, 6 kΩ, 4.8 kΩ, and 4 kΩ respectively, so that in parallel with the 600Ω resistor 41 they produce resistance values of about 569.2Ω, 558.1Ω, 545.5Ω, 533.3Ω, and 521.7Ω respectively. Thus the resistors 42 to 46 are in a sequence reverse to that of the resistors 32 to 36.

As illustrated by way of example in FIG. 2, the switches 38 and 48 are controlled by the decoder 24 so that the resistor 33 is connected in parallel with the resistor 31 and so that the resistor 43 is connected in parallel with the resistor 41. Thus in this switch state the bottom resistance 27 is 2031Ω+533.3Ω and the top resistance is 2031Ω+558.1Ω, corresponding to an offset trim of −0.625 mV or −¼ LSB. The switches 38 and 48 are all controlled similarly in pairs for selecting the resistors for connection in parallel with the resistors 31 and 41, in each case so that the sum of the bottom and top resistances is substantially constant.

By way of example, the offset trim decoder 24 can provide the following decoding of the 3-bit OFST signal for respective offset adjustments:

| OFST code | Adjustment |
|---|---|
| 000 | +½ LSB |
| 001 | +¼ LSB |
| 010 | 0 (default) |
| 011 | −¼ LSB |
| 100 | −½ LSB |
| other | not applicable |

For example, it may be determined that it is necessary to make a +½ LSB adjustment in order to cancel a −½ LSB of ADC offset. This means that it is necessary to shift the voltage Vbot up by ½ LSB, or about 23.5 mV. This is effected by the offset trim decoder 24 controlling the switches 38 to connect the 11.1 kΩ resistor 36 in parallel with the 600Ω resistor 31. At the same time, the offset trim decoder controls the switches 48 to connect the 4 kΩ resistor 46 in parallel with the 600Ω resistor 41, so that the full-scale voltage range of the ADC is maintained substantially constant by increasing the voltage Vtop by ½ LSB.

If required, digital offset cancellation techniques can also be used to provide +/−one LSB voltage shifts in known manner.

The parallel resistor trimming described above requires increased area and increases parasitic capacitor loading of the output of the amplifier 10 providing the ADC voltage reference Vref. These increases can be minimized by optimum selection of the arrangement and switching of the resistors constituting the bottom and top resistances 27 and 28. In other embodiments of the invention, the resistors 30 and 40 can have resistances different from one another, and either or both of them can be omitted. Further, a different trimmable resistor arrangement can be provided for each of the bottom and top resistances 27 and 28, as may be desired. For example, resistors can be provided in series and/or parallel, and can be switched individually or in combinations to provide the desired resistance trimming. However, a parallel arrangement such as that of FIG. 2 may be preferred because it facilitates making relatively small trimming steps or resistance changes.

It can be appreciated from the above description that embodiments of the invention simplify the calibration or trimming of the ADC by making the offset trim independent of the gain trim, this being achieved by equal and opposite trimming of two resistances at opposite ends of the resistance ladder. Thus one resistance is increased and the other resistance is decreased so that a total resistance of the resistance ladder remains substantially constant, and hence offset trimming does not change the LSB voltage or the full-scale range of the ADC.

Although the invention is described above in the context of a particular form of ADC, it can be appreciated that it may be applied to other forms of ADC or to any other circuit that uses a resistance ladder to provide a plurality of voltages. For example, such other forms of ADC may include a Flash ADC, and such other circuit may include a digital-to-analog converter (DAC).

Thus although particular forms and details of an ADC are described above, it should be appreciated that these are given by way of example only, that the invention is not limited to these, and that numerous modifications, variations, and adaptations may be made without departing from the scope of the invention as defined in the claims.

1. A circuit including a resistance ladder comprising a plurality of resistors connected in series between first and second adjustable resistances via which a voltage difference is supplied to the resistance ladder, so that taps of the resistance ladder provide respective voltage levels over a voltage range, and a control circuit for making substantially equal and opposite changes to the first and second adjustable resistances to shift the voltage range without changing a magnitude of the voltage range.

2. A circuit as claimed in claim 1 wherein the circuit comprises an analog-to-digital converter (ADC) and the respective voltage levels provided by taps of the resistance ladder constitute comparison voltage levels for the ADC.

3. A circuit as claimed in claim 1 wherein said plurality of resistors of the resistance ladder have equal resistances.

4. A circuit as claimed in claim 1 wherein the first and second adjustable resistances connect the resistance ladder to a reference voltage and to a common voltage.

5. A circuit as claimed in claim 1 wherein each of the first and second adjustable resistances comprises a first resistor and a plurality of second resistors for connection selectively in parallel with the first resistor.

6. A circuit as claimed in claim 5 wherein the circuit comprises an analog-to-digital converter (ADC) and the respective voltage levels provided by taps of the resistance ladder constitute comparison voltage levels for the ADC, the ADC and the resistance ladder comprising parts of an integrated circuit.

7. An analog-to-digital converter (ADC) comprising:
a circuit for producing a reference voltage relative to a common voltage;
a resistance ladder comprising a plurality of resistors connected in series between first and second adjustable resistances, the reference voltage and the common voltage being applied to the resistance ladder via the first and second adjustable resistances respectively, taps of the resistance ladder providing respective comparison voltage levels over a voltage range of the ADC; and
a control circuit for making substantially equal and opposite resistance changes to the first and second adjustable resistances to shift the voltage range of the ADC without changing a magnitude of the voltage range.

8. An ADC as claimed in claim 7 wherein the plurality of resistors of the resistance ladder have equal resistances.

9. An ADC as claimed in claim 7 wherein each of the first and second adjustable resistances comprises a first resistor and a plurality of second resistors for connection selectively in parallel with the first resistor.

10. An ADC as claimed in claim 9 wherein the ADC is part of a CMOS integrated circuit.

11. An ADC as claimed in claim 7 wherein the circuit for producing a reference voltage relative to a common voltage comprises an amplifier for multiplying a voltage supplied to the amplifier in accordance with a gain of the amplifier determined by a resistance ratio.

12. A method of trimming a resistance ladder, the resistance ladder comprising a plurality of resistors connected in series and having taps providing respective voltage levels over a voltage range in response to a voltage difference supplied to the resistance ladder, the method comprising the steps of:
supplying a voltage difference to the resistance ladder via first and second adjustable resistances at first and second ends of the plurality of resistors connected in series; and
making substantially equal and opposite changes to the first and second adjustable resistances to shift the voltage range without changing its magnitude.

13. A method as claimed in claim 12 wherein each of the first and second adjustable resistances comprises a first resistor and a plurality of second resistors, and the step of making substantially equal and opposite changes to the first and second adjustable resistances comprises, for each of the first and second adjustable resistances, connecting a selected one of the second resistors in parallel with the first resistor.

14. A method as claimed in claim 13 wherein the step of making substantially equal and opposite changes to the first and second adjustable resistances is a step in fabricating an integrated circuit including the resistance ladder.

15. A method as claimed in claim 11 and comprising the steps of producing the voltage difference using an amplifier having a gain determined by a resistance ratio, and adjusting a resistance of at least one resistor to control the resistance ratio thereby to determine the gain of the amplifier.

16. A method as claimed in claim 15 wherein the resistance ladder and amplifier are parts of an analog-to-digital converter (ADC), and said steps of making substantially equal and opposite changes to the first and second adjustable resistances and adjusting the resistance of at least one resistor comprise independent steps of adjusting offset and gain respectively of the ADC.

17. A method as claimed in claim 16 wherein each of the first and second adjustable resistances comprises a first resistor and a plurality of second resistors, and the step of making substantially equal and opposite changes to the first and second adjustable resistances comprises, for each of the first and second adjustable resistances, connecting a selected one of the second resistors in parallel with the first resistor.

18. A method as claimed in claim 17 wherein the step of making substantially equal and opposite changes to the first and second adjustable resistances is a step in fabricating a CMOS integrated circuit including the ADC.

19. A method as claimed in claim 16 wherein the step of making substantially equal and opposite changes to the first and second adjustable resistances is a step in fabricating a CMOS integrated circuit including the ADC.
